(19) United States
(12) Patent Application Publication
(10) Pub. No.: US 2006/0243961 A1
(43) Pub. Date: Nov. 2, 2006

(54) Adaptive quantum design for QCSE devices and nanophotonic devices

(75) Inventors: Anthony Levi, Los Angeles, CA (US); Stephan Haas, Los Angeles, CA (US)

Correspondence Address: MCDERMOTT, WILL & EMERY, Suite 3400, 2049 Century Park East, Los Angeles, CA, 90067, US

(73) Assignee: University of Southern California

(21) Appl. No.: 11/215,251

(22) Filed: Aug. 30, 2005

Related U.S. Application Data
(60) Provisional application No. 60/606,291, filed on Sep. 1, 2004.

(51) Int. Cl. H01L 31/00

(52) U.S. Cl. 257/21

(57) ABSTRACT

A QCSE device may have a semiconductor quantum well structure, with an energy band profile defined by a broken-symmetry quantum well potential V(x). The quantum well potential V(x) may be identified by adaptive numerical searches performed by a processing system, which uses adaptive algorithms to numerically optimize the quantum well potential, so as to most closely match a desired optical response of the QCSE device to incident optical radiation. A nanophotonic device may include a plurality of dielectric scattering centers distributed within a substantially uniform medium in an aperiodic, broken-symmetry spatial configuration. The spatial configuration of the dielectric elements may be numerically computed and optimized using iterative techniques, so as to most closely generate a desired target function response from the nanophotonic device.

### CROSS REFERENCE TO RELATED APPLICATIONS

This application claims the benefit of priority under 35 U.S.C. § 119(e) from co-pending, commonly owned U.S. provisional patent application Ser. No. 60/606,291, filed on Sep. 1, 2004, entitled “Adaptive Design of Semiconductor Electronic and Optoelectronic Devices Using Inverse Solver Techniques.” The entire content of this provisional application is incorporated herein by reference.

### GOVERNMENT'S INTEREST IN APPLICATION

This invention was made with government support under DARPA Grant No. 53-4502-8001 awarded by the United States Government. The government may have certain rights in the invention.

### BACKGROUND

A number of devices make use of the optical properties of nanoscale photonic and/or semiconductor structures. As one example, researchers have developed nanophotonic devices that include nanoscale dielectric scattering centers embedded in a uniform medium. The spatial arrangement of these dielectric scattering centers within the medium may strongly influence the propagation of incident electromagnetic waves.

Researchers have typically designed these nanophotonic devices based on spatially periodic photonic crystal (PC) structures. Researchers have studied these symmetric PCs, and applied them to both optics and microwaves. They have also introduced point and line defects in spatially periodic PCs, in order to filter, demultiplex, and guide electromagnetic waves.

There may be numerous unresolved design issues, however, with PC inspired devices. These unresolved issues limit the prospects of practically adopting these devices in optical systems. For example, when coupling between standard fibers or between waveguides and PC waveguides, the back reflection may either be unacceptably large, or may require use of relatively large coupling regions. As another example, the finite size of the PCs may have a dramatic and detrimental impact on device performance. Solutions to these and other similar problems may be stymied by the limited number of degrees of freedom that are inherent in spatially periodic PC designs. Spatially symmetric PC crystals may impose constraints of spatial symmetry, which may cause difficulties when attempting to design photonic devices having desired functionalities.

As another example, quantum confined Stark effect (QCSE) devices make use of an electroabsorption mechanism that may only be seen in quantum well structures, namely the occurrence in quantum well materials of a relatively large change in optical absorption, when an electric field is applied perpendicular to the surface of the quantum well.

Photon absorption by direct band gap semiconductors typically involves the creation of excitons. Excitons are bound states of an electron and a hole in a semiconductor (or insulator), i.e. are Coulomb-correlated electron-hole pairs. In direct band gap semiconductor quantum well structures, optical absorption at near band gap photon energies may be dominated by the presence of these excitons. Therefore, excitonic optical absorption at near-band-gap photon energies in semiconductor quantum well structures is of great interest for device applications.

By applying an electric field perpendicular to the plane of the quantum well, as described above, the excitonic optical absorption strength and energy can be manipulated. The change in optical absorption caused by the applied electric field is generally referred to as a “quantum-confined Stark effect” (QCSE). Compared to bulk semiconductors, the excitonic absorption strength in QCSE structures may be greater, even in the presence of a large externally applied electric field. This performance advantage may be one of the reasons why the quantum-confined Stark effect has been used to design many optical modulators and detectors.

Typically, these designs may make use of simple rectangular potential wells. However, these ad hoc approaches to device design may not fully exploit the ability of modern crystal growth techniques to vary the quantum well potential profile on an atomic monolayer scale in the growth direction.

In sum, the design of QCSE devices and/or nanophotonic devices may have developed in an ad-hoc fashion, incrementally building on previous designs and concepts. In order to optimize device performance and/or implement new and desirable functionalities for these photonic and semiconductor devices, techniques that go beyond the above-described cycle of ad-hoc and piecemeal design may be needed.

### SUMMARY

A QCSE device may include a semiconductor quantum well structure having an energy band profile defined by a broken-symmetry quantum well potential, and a processing system. The processing system may be configured to adaptively search for and numerically optimize the broken-symmetry quantum well potential, in order to most closely match a desired target response of the QCSE device to incident optical radiation.

A nanophotonic device may include a plurality of dielectric elements arranged within a substantially uniform medium in an aperiodic spatial configuration, each of the dielectric elements configured to scatter incoming optical radiation. The nanophotonic device design may further include a processing system adapted to compute and optimize the spatial configuration of the dielectric elements within the medium in order to most closely generate a desired target function response from the nanophotonic device in response to incoming optical radiation or a source of optical radiation within the device.

A nanophotonic device may include a plurality of dielectric elements distributed in an aperiodic, broken-symmetry spatial configuration. Each dielectric element may be configured to scatter optical radiation. The spatial configuration of the dielectric elements may be numerically computed and optimized so as to most closely generate a desired target function response from the nanophotonic device in response to incoming optical radiation.

A QCSE (quantum confined Stark effect) device may include a semiconductor quantum well structure having an energy band profile defined by a broken-symmetry quantum well potential V(x). The quantum well structure may include a plurality of semiconductor layers having different band gap energies. The broken-symmetry quantum well potential V(x) may be numerically computed and optimized so as to most closely match a desired target response of the QCSE device to incident optical radiation.

### BRIEF DESCRIPTION OF THE DRAWINGS

FIG. 1A is a schematic block diagram of a QCSE (quantum confined Stark effect) device, in accordance with one embodiment of the present disclosure.

FIG. 1B schematically illustrates an energy band profile of a structure containing a single quantum well.

FIG. 2A illustrates an absorption spectrum of a rectangular quantum well.

FIG. 2B illustrates a broken-symmetry double quantum well, in an embodiment in which the potential well width and depth parameters are numerically optimized. FIG. 2B also illustrates the resulting excitonic absorption spectrum.

FIG. 3 illustrates a broken-symmetry quantum well structure obtained from numerical optimization, with additional search parameters compared to FIGS. 2A and 2B, and also illustrates the resulting excitonic absorption spectrum.

FIG. 4A illustrates the positions of the dielectric cylinders, and the distribution of the Poynting vector field, in an initial configuration at the beginning of the numerical iteration, in an embodiment in which the nanophotonic device includes 56 dielectric cylinders in air and the target function response is a top-hat intensity distribution of the scattered radiation.

FIG. 4B illustrates the computed angular intensity distribution for the initial configuration shown in FIG. 4A, compared with the target distribution.

FIG. 5A illustrates the positions of the dielectric cylinders, and the distribution of the Poynting vector field, in the numerically optimized configuration obtained after 9700 iterations, in an embodiment in which the nanophotonic device includes 56 dielectric cylinders in air and the target function response is a top-hat intensity distribution of the scattered radiation.

FIG. 5B illustrates the computed angular intensity distribution after 9700 iterations for the cylinders shown in FIG. 5A, compared with the target distribution.

FIG. 5C illustrates a contour plot of the electric field magnitude after 9700 iterations, for the embodiment illustrated in FIGS. 5A and 5B.

FIG. 5D illustrates the evolution of the error, as a function of the number of iterations, for the embodiment illustrated in FIGS. 5A, 5B, and 5C.

FIG. 6A illustrates for comparison the positions of the dielectric cylinders, and the distribution of the Poynting vector field, in a spatially symmetric, periodic photonic crystal with 56 dielectric cylinders in air.

FIG. 6B illustrates the computed angular intensity distribution for the periodic photonic crystal, compared with the target distribution, in the embodiment illustrated in FIG. 6A.

FIG. 7A illustrates the positions of the dielectric cylinders, and the distribution of the Poynting vector field, in an initial configuration (at the beginning of the iteration) of dielectric cylinders in a nanophotonic device with 26 dielectric cylinders embedded in Si, in an embodiment in which the target function response is a cosine squared intensity distribution.

FIG. 7B illustrates the computed angular intensity distribution for these cylinders, compared with the target distribution, in the embodiment shown in FIG. 7A.

FIG. 8A illustrates the positions of the dielectric cylinders, and the distribution of the Poynting vector field, in a numerically optimized spatial configuration of 26 dielectric cylinders embedded in Si, in an embodiment in which the target function response is a cosine squared intensity distribution of the scattered radiation.

FIG. 8B illustrates the computed angular intensity distribution for the 26 cylinders illustrated in FIG. 8A after 7000 iterations, compared with the target intensity distribution, in the embodiment illustrated in FIG. 8A.

FIG. 8C illustrates a contour plot of the magnetic field magnitude in relative units, after 7000 iterations, in the embodiment illustrated in FIGS. 8A and 8B.

FIG. 8D illustrates the evolution of the error, as a function of iteration number, in the embodiment illustrated in FIGS. 8A, 8B, and 8C.

### DETAILED DESCRIPTION

In Section I of the present disclosure, an adaptive quantum design methodology is disclosed, which identifies broken-symmetry quantum-well potential profiles that can generate superior optical response properties, and which can be used to find a desired target response best suited for a QCSE device. A numerical search of the design space is performed in order to find a broken-symmetry quantum well potential profile V(x) that most closely approaches the target response. The exciton many-body wave function is manipulated by varying the potential profile V(x), to achieve a desired behavior.

In Section II of the present disclosure, adaptive designs of nanophotonic devices are described which allow the photon scattering properties of aperiodic nanoscale dielectric structures to be tailored to closely match a desired response. The broken symmetry of aperiodic designs may provide access to device functions that may be unavailable to periodic photonic crystal structures.

I. Adaptive Quantum Design for QCSE Devices

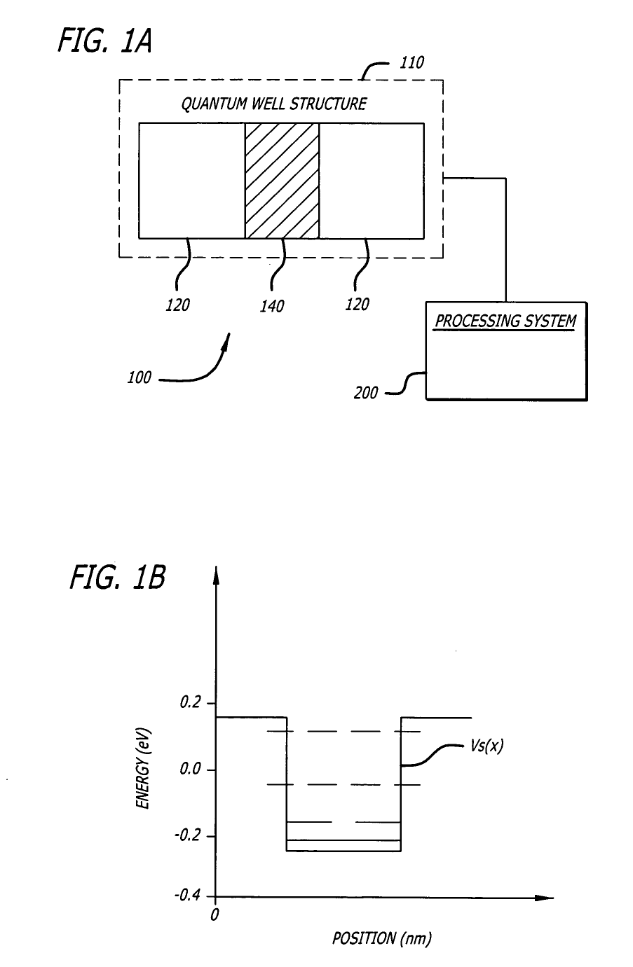

FIG. 1A is a schematic block diagram of a QCSE (quantum confined Stark effect) device 100, in accordance with one embodiment of the present disclosure. In overview, the QCSE device 100 includes a semiconductor quantum well structure 100, and a processing system 200 configured to adaptively search for and numerically optimize a broken-symmetry quantum well potential for the quantum well structure 110, in order to most closely match a desired target response of the QCSE device to incident optical radiation. As described in more detail below, the processing system 200 is configured to implement adaptive algorithms in order to numerically search for, and optimize, the asymmetric quantum well potential.

The processing system 200 may implement the methods, systems, and algorithms described in the present disclosure, using computer software. The methods and systems in the present disclosure are not described with reference to any particular programming language. It will be appreciated that a variety of programming languages may be used to implement the teachings of the present disclosure. The processing system 200 may be selectively configured and/or activated by a computer program stored in the computer. Such a computer program may be stored in any computer readable storage medium, including but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions. The methods, algorithms, and systems presented herein are not inherently related to any particular computer, processor or other apparatus. Various general purpose systems may be used with different computer programs in accordance with the teachings herein. Any of the methods, systems, and algorithms described in the present disclosure may be implemented in hard-wired circuitry, by programming a general purpose processor, a graphics processor, or by any combination of hardware and software.

In the quantum well structure 100, a thin layer 140 of a first semiconductor material is sandwiched between two thicker layers 120 of a second semiconductor material with a larger energy band gap. The first semiconductor layer 140 has a thickness smaller than the extension of the envelope wave function of electrons and holes, and has a lower energy band gap, compared to the energy band gap of the second semiconductive layer 120. The electron and hole envelope wave function is confined in a direction perpendicular to the layers, and are plane waves in a parallel directions.

In quantum well structures, particles are confined in the first, lower band gap energy layer, and the energy levels of the particles are significantly modified by the quantum confinement. For illustrative purposes, FIG. 1B schematically shows an energy band profile of a structure containing a single quantum well. For simplicity, a simple rectangular quantum well potential is illustrated. A series of confined electron and hole levels are produced inside the quantum well, as shown in FIG. 1B.

Quantum well structures may cause excitons to be created, when photons of the incident optical radiation are absorbed. The absorption of photons in a direct band gap semiconductor may involve creation of electron-hole pairs. For uncorrelated electron-hole pairs, absorption may occur at photon energies greater than the band gap energy of the material. However, the Coulomb interaction between an electron and hole may form a correlated exciton bound state, with an absorption energy less than the band gap energy. The binding energy of this exciton may be increased by confining both the electron and the hole within the quasi two-dimensional quantum well structure. The absorption spectrum that emerges from this quantum well potential profile shows a strong peak just below the band gap energy. This fact may have been exploited for use in many modern optoelectronic devices such as modulators and detectors.

In one embodiment of the present disclosure, the QCSE may be modeled using a two band tight-binding Hamiltonian of the semiconductor single electron states. A variational method may be used to find the exciton binding energy. In this embodiment, the processing system 200 may be configured to use a variational ansatz for the exciton wave function, that depends upon a variational parameter λ. The processing system may be further configured to vary the parameter λ to minimize the exciton binding energy and to optimize the exciton wave function. The processing system may be configured to compute a contribution of the excitons to an absorption spectrum of the photons so as to generate the exciton absorption spectrum.

In this embodiment, the effective masses of the electron (mₑ*=0.067 m₀) and the heavy hole (mₕ*=0.34 m₀) determine the tight-binding hopping parameters tₑ=1.787 eV and tₕ=0.35 eV. The conduction and valence band potential profiles are calculated using the band gap energy E_{g}=(1.426+1.247x)eV and a band gap offset ratio between conduction and valence band of 67/33. The effective electron mass in the conduction band is
mₑ=(0.067+0.0835x)m₀
and the effective hole mass in the valence band is
mₕ=(0.34+0.42x)m₀.

The 1s exciton wave functions may have the form:
Ψₑₓ(xₑ,xₕ,ρ)=\sqrt{2/π}φₑ(xₑ)φₕ(xₕ)exp(−ρ/λ)/λ.
In the above equation, ρ denotes the separation between the electron and the hole in the plane of the quantum well and perpendicular to the applied field F,xₑ, and xₕ are the coordinates of the electron and the hole perpendicular to the plane of the quantum well, φₑ(xₑ) and φₕ(xₕ) are the single particle wave functions for the electron and the hole, and λ is the variational parameter.

The processing system 200 may optimize this wave function, by minimizing the exciton binding energy. The processing system 200 may then calculate the exciton contribution to the photon absorption spectrum, governed by the spatial overlap of the electron and hole wave functions. The contribution of the particle-hole continuum may be included to account for the complete absorption spectrum.

To minimize computation time, the discretization of the quantum well band-edge profile into atomic monolayers may be incorporated by using a nearest-neighbor tight-binding Hamiltonian to find the single-particle eigenfunctions in the direction of the applied electric field, which may be referred to as the x-direction, for convenience.

The nearest neighbor Hamiltonian H_{unc} for the uncorrelated electrons and holes is given by

$$\begin{matrix}{H}_{unc} = {H}_{e} + {H}_{h} \\ = - {t}_{e} {\sum }_{< i , j >} ( {c}_{ei}^{+} {c}_{ej} + {c}_{ej}^{+} {c}_{ei} ) + {\sum }_{i} {ɛ}_{ei} + {t}_{h} {\sum }_{< i , j >} ( {c}_{hi}^{+} {c}_{hj} + {c}_{hj}^{+} {c}_{hi} ) + \\ {\sum }_{i} {ɛ}_{hi} ,\end{matrix}$$

In the above equation for H_{unc}, tₑ and tₕ represent the electron and hole hopping energies, respectively; εₑ denotes an onsite electron energy; εₕ denotes an onsite hole energy; cₑ⁺ and cₑ denote an electron creation and an electron annihilation operator, respectively; cₕ⁺ and cₕ denote a hole creation and a hole annihilation operator, respectively; and <i, j> indicates a sum over nearest neighbors only.

As described above, a variational ansatz may be used to obtain the separable 1s exciton wave function
ψ^{ex}(zₑ,zₕ,ρ)=φₑ(zₑ)φₕ(zₕ)φ(ρ) (5)
in which the in-plane exciton wave function takes the form

$$ϕ ( ρ ) = \sqrt{\frac{2}{{πλ}^{2}} {ⅇ}^{- ρ / λ}}$$

where the in-plane coordinate is ρ=\sqrt{x²+y²}. The exciton wave function may found by varying the parameter λ, to minimize the exciton binding energy using the Hamiltonian for the exciton, i.e. the correlated electron-hole pair:

$${H}_{ex} = {H}_{e} + {H}_{h} - \frac{{h}^{2} {∇}_{ρ}^{2}}{2 μ} - \frac{{ⅇ}^{2}}{4 {πɛ}_{0} {ɛ}_{r}} \frac{1}{\sqrt{{ρ}^{2} + {( {z}_{e} - {z}_{h} )}^{2}}}$$

In the above expression for Hₑₓ, the first two terms are constant with respect to λ, the third term represents the in-plane kinetic energy of the electron and hole about their center of mass, and the final term is the coulomb potential energy. Here, μ is the reduced mass, εᵣ is the relative dielectric permittivity, and zₑ and zₕ are the z positions of the centers of mass of the electron and the hole, respectively. The variational method described above may accurately model excitonic absorption for quantum well profiles.

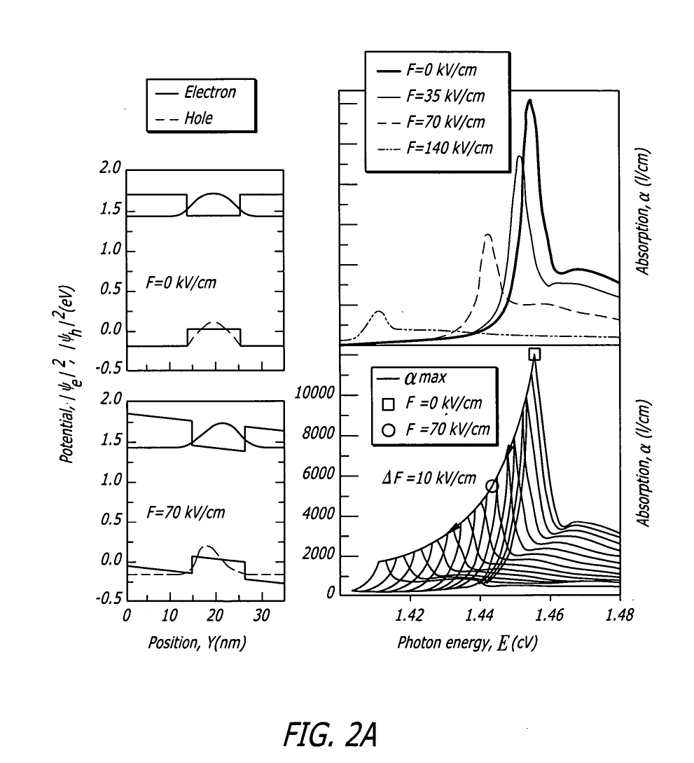

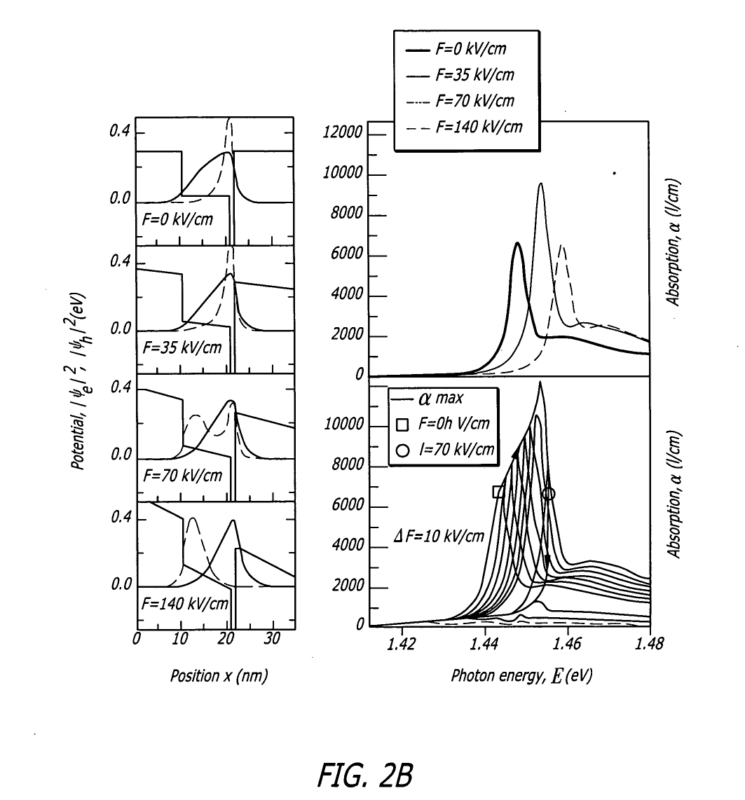

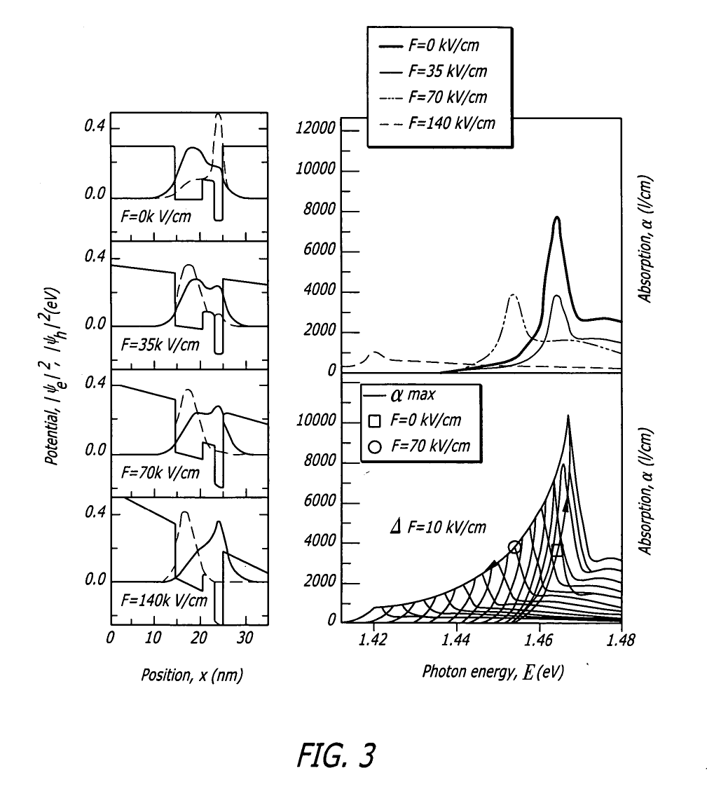

When a uniform electric field F is applied in the x-direction, perpendicular to the plane of the quantum well, the band-edge potential profile may change. In FIGS. 2A, 2B, and 3 below, the conduction and valence band-edge profiles are shown as a function of position x along with the lowest-energy single-particle probability distribution for electrons, |ψₑ|², and for holes, |ψₕ|². With increasing applied electric field in the x-direction, electron and hole tunneling results in a decrease of the exciton absorption peak energy. Shifts in the distribution of the electron and hole wave functions lead to a reduction in spatial overlap which in turn reduces the dipole matrix element, diminishing the peak absorption strength.

FIG. 2A illustrates the calculated absorption spectra, α, for the case of a symmetric, rectangular quantum well potential. The absorption spectra a is shown as a function of photon energy E, for different electric fields F applied along the x direction. As seen on the left-hand side of FIG. 2A, an increase of the field strength leads to a tilt of the confining potential. Consequently, the electron wave function is shifted towards the right, whereas the hole wave function moves to the left, resulting in a reduced spatial overlap. This in turn causes (i) a shift towards lower energy, and (ii) a strong reduction in spectral weight of the dominant excitonic contributions to the photon absorption spectrum.

On the lower-right-hand side of FIG. 2A, the calculated peak exciton absorption is shown as a function of photon energy for applied electric fields in the range of 0 kV/cm<F<140 kV/cm. The arrow indicates the direction of increasing applied electric field. Shown as thinner curves are individual spectra in 10 KV/cm field increments used to calculate the exciton peak absorption curve. This exciton absorption curve captures an essential functionality of the QCSE. Maximum exciton absorption decreases and shifts to lower photon energy with increasing applied electric field. This rapid loss of resonant behavior in the presence of a bias voltage dramatically limits the tenability of quantum well based optical devices.

In the present disclosure, an adaptive design methodology is described that may create a number of different types of desirable functionalities. For example, in one embodiment a device may be designed in which the excitonic absorption peak at F=0 kV/cm and F=70 kV/cm is the same, only shifted in photon energy by at least 10 meV. This particular functionality would allow a user to rapidly switch the frequency of a quantum well exciton absorption resonance, without loss of its absorption strength. Initially, the search for an enabling broken-symmetry structure may be constrained to double wells with variable depths and widths. In this embodiment, the processing system 200 may perform a numerical optimization using a genetic algorithm with a fitness function that simultaneously optimizes the strength and separation of the exciton absorption peak at zero and finite (70 kV/cm) electric field.

FIG. 2B illustrates the optimal solution found by the above-described adaptive quantum design method, for this type of restricted search. As seen in FIG. 2B, the optimized double well causes the ground state wave function of the hole (cf. broken curve) to develop two maxima whose relative weight is shifted from left to right as the electric field is increased. Simultaneously, the center of the electron wave function (solid curve) moves from left to right, having a maximum spatial overlap with the right peak of the hole wave function at F=70 kV/cm. The resulting exciton peaks in the absorption spectrum, shown on the right side of FIG. 2B, have the desired strength and separation. They are located on two sides of a maximum resonance that is reach at F=20 kV/cm.

In this broken symmetry structure, the maximum of the excitonic absorption peak (αₘₐₓ) initially increases with applied field, and then drops. The corresponding shift of the resonant energy is also nonmonotonic.

Further optimized solutions may be found that are even closer to a desired response, if the arbitrarily imposed initial constraints on the numerical search performed in conjunction with FIG. 2B are relaxed. FIG. 3 shows the result of a numerical optimization of the quantum well in which the positions of the corners of the double wells are allowed to overlap. As seen in FIG. 3, the potential profile that is obtained as a result of this numerical optimization is very simple. The steep drop of V(x) close to the right boundary of the well pins the hole wave function (shown as a broken curve), whereas the electron wave function (shown as a solid curve) is still able to shift its weight with increasing applied electric field. The resulting exciton resonances in α(E) at F=0 kV/cm and 70 kV/cm are more pronounced, compared to the solution shown in FIG. 2B.

Furthermore, in the design shown in FIG. 3, the exciton absorption curve peak (αₘₐₓ) exhibits a functionality that is different from the one shown in FIG. 2B. It first shifts towards higher energies with increasing applied electric field before it drops rapidly and eventually shifts back towards lower photon frequencies. It should be noted that an almost vertical drop of α(E) in a very narrow range of electric fields indicates an exponential sensitivity that is highly desirable for the design of quantum well based modulators.

In sum, in section I of this disclosure the adaptive quantum design methodology described above for QCSE devices reveals previously unexplored design options. The large number of possible solutions along with their exponential sensitivity to small parameter changes render the problem prohibitive to searches by hand. Instead, numerical searches identify optimized broken-symmetry structures which enable desired target functionalities that are useful in the design of quantum-well based photonic switches and modulators. The above-described approach may allow users to engineer many-body excitonic wave functions, illustrating another paradigm in nanoscale design.

II. Adaptive Design for Nanophotonic Devices

In another embodiment of the present disclosure, a spatial arrangement of nanoscale dielectric scattering centers that optimally matches a desired or target response from a nanophotonic device is computed numerically, by iteratively solving an inverse problem, as described below. The efficiency of the adaptive algorithms used to find the solutions may become an increasingly critical issue as the number of scattering centers, N increases. Even for modest values of N, however, the methods, algorithms, and systems described below may enable users to create nanophotonic device designs that may outperform approaches based on spatially periodic photonic crystal structures.

In overview, a nanophotonic device is described that includes a plurality of dielectric elements or scattering centers placed within a substantially uniform medium, and a processing system that performs iterative numerical optimizations to find an optimized spatial configuration of the dielectric elements that best generates a desired response. The dielectric elements may be substantially lossless dielectric rods placed in air, for example. An optical source may generate input optical radiation that is scattered by the plurality of dielectric elements. An optical detector may detect and measure the optical response from the nanophotonic device.

As described below, the optimized configuration of the dielectric scattering centers is an aperiodic, broken-symmetry configuration, resulting from a breaking of a symmetry in the spatial arrangement of the elements. The optimization process may be an iterative procedure, in which the scattered field from a trial configuration of cylindrical rods or circular holes is compared with that of the target. The computation of the scattered field may be referred to as the forward problem. In the embodiments described below, an input optical beam of Gaussian profile may be scattered by an angle of 45°. The scattering angle may be defined with respect to the original direction of propagation of the wave, so that the backscatter corresponds to a scattering angle of 180°.

The numerical optimization may be performed based on a guided random walk method. In short, the positions of individual cylinders may be randomly changed by a small amount, and the scattered fields in the modified configuration may be calculated. If the result is closer to the target function, such that the error (described in more detail below) is decreased, then the new configuration is accepted, otherwise it is rejected. The actual implementation of the adaptive algorithm may also include other types of collective motion such as moving more than one cylinder per iteration, and moving or rotating a group of cylinders.

In general, the target function may be any electromagnetic distribution. A typical target function might involve redirecting and reshaping the input beam. Because the target function may specify the field distribution of a guided mode, it may be possible to create mode converters to interface between a fiber or ridge waveguide and a PC waveguide. An incoming electromagnetic beam may be redirected and reshaped, using optimized aperiodic nanostructures.

By using adaptive algorithms, an electromagnetic field distribution may always result that approximates the desired target function to some degree. The closeness to the desired field distribution may depend on the number of dielectric scatters N, as well as other constraints. One analogy may be the multipole expansion of fields where using higher order multipoles assures a better approximation, but at the expense of increased computational effort.

In one embodiment, the desired target function is a top hat distribution of the optical intensity with respect to the scattering angle. In another embodiment, the desired target function may be a cosine squared distribution of the intensity. Both embodiments are described below. It should of course be appreciated that the target function may include many other types of optical intensity distributions, in different embodiments of the methods and systems described in the present disclosure.

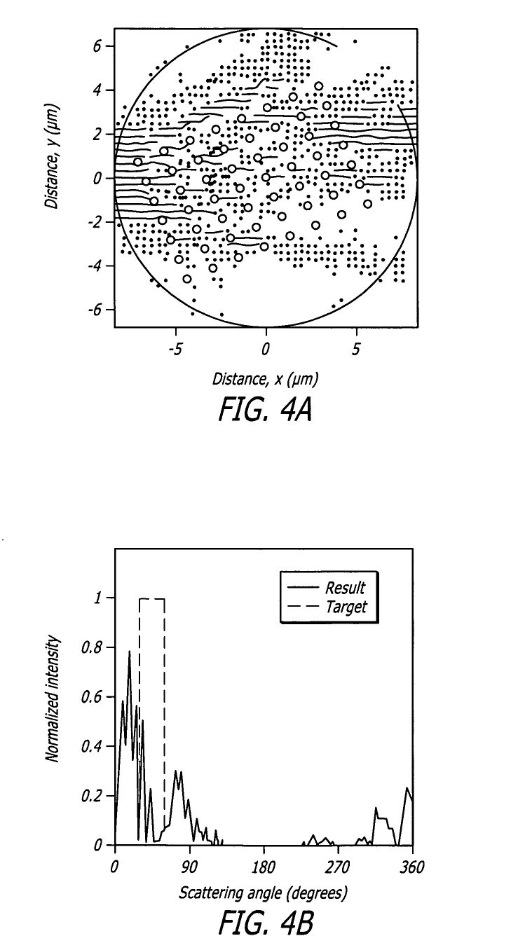

FIGS. 4A and 4B illustrate an initial configuration of dielectric elements and the resulting target distribution, at the beginning of the iteration, in an embodiment in which the target function response is a top-hat intensity distribution of the scattered radiation. FIG. 4A illustrates the initial positions of the dielectric cylinders, and the distribution of the Poynting vector field, in a nanophotonic device that has 56 dielectric cylinders positioned in air. FIG. 4B illustrates the computed angular intensity distribution for these cylinders, compared with the target distribution.

In the illustrated embodiment, optimization of a top-hat intensity distribution target function is performed starting from a configuration of N=56 dielectric rods, which are represented in FIG. 4A by the small circles, each having a refractive index n=1.5, and diameter d=0.4 μm. The top-hat intensity function is difficult to achieve, even approximately, in optical systems based on periodic photonic crystals. Applications of top-hat intensity distributions include achieving a substantially uniform illumination of the active area of a photodetector.

The medium surrounding the rods is air and the structure is illuminated by a TM polarized (electric field along the z direction) Gaussian beam of width 4 μm, wavelength λ=1 μm, which propagates along the positive x direction (from left to right in FIG. 4A). The initial configuration of the rods and intensity distribution are illustrated in FIG. 4A, where the arrows represent in arbitrary units the real part of the Poynting vectors. The target function window, represented in FIG. 4A by a missing arc in the 7 μm radius observation circle, extends from 30° to 60°.

FIG. 4B shows the normalized intensity, i.e. the real part of the normal component of total field Poynting vectors directed outwards, as a function of angle on an radius of 7 μm from the center of the symmetric array. FIG. 4B shows that, for the initial configuration, the overlap with the top-hat function, shown as a broken line, is poor.

The numerical procedures that may be implemented in order to improve the match with the desired top-hat distribution includes solving the electromagnetic field equations (the “forward” problem), which will now be described in more detail. In the embodiment illustrated in FIGS. 4A and 4B, the dielectric elements are a set of N long, parallel, lossless circular dielectric rods distributed in a substantially uniform medium, namely air, and illuminated by an electromagnetic wave perpendicular to the axis of the cylinders. The geometry of such a system may lend itself to use of a 2D electromagnetic field solver. When analyzing scattering from one cylinder, the solution, expressed as a Fourier-Bessel series, may readily be found by imposing the continuity of the electric and magnetic field components at the rod surface. When studying scattering from two or more cylinders, however, multiple scattering gives an additional linear system that has to be solved in order to find the Fourier-Bessel coefficients. For a given number of Bessel functions, this linear system has a reduced form which may be conveniently described using the scattering matrix method. The input wave may be of arbitrary shape so long as it is expressed as a Fourier-Bessel series.

Considering only TM polarized electromagnetic waves, for simplicity, the total field may be written as the sum of the incident field E_{inc} and the field E_{sc} scattered from the cylinders: E=E_{inc}+σᵢ^{N}=1σ_{sc}ⁱ. The actual incident field on a cylinder labeled with index j is E=E_{inc}+Σᵢ^{N}≠ⱼE_{sc}^{I}. The user of the methods and systems described herein must solve the Helmholtz equation for the total field, ∇²E+k²E=0, where k=k₀ in the region outside the cylinders and k=k₁ inside the cylinders. Separation of variables in polar coordinates may be used to solve this equation.

All field quantities may be written in the form of Fourier-Bessel series with the coefficients αₘ and βₘ determined from the boundary conditions. Hence, E=Σₘ^{∞}=−∞αₘZₘ(kp)e^{imθ}+σₘ^{∞}= . . . ∞βₘ\tilde{Z}ₘ(κρ)e^{imθ}, where Zₘ and \tilde{Z}ₘ are two conjugate cylindrical functions. These functions may either be the first order Bessel functions Jₘ and Yₘ or the second order Bessel functions (Hankei functions) Hₘ⁽¹⁾ and Hₘ⁽²⁾. The pair chosen may depend on the boundary conditions. Outside the cylinders, the asymptotic behavior may determine which functions are used. Since only the Hₘ⁽²⁾ function has the behavior of an out-propagating cylindrical wave, the field of the scattered wave E_{sc} is written using only Hₘ⁽²⁾, from the {Hₘ¹,Hₘ²} pair. Hence, the scattered field is E_{sc}=Σ_{in=-∞}^{∞}bₘHₘ⁽²⁾(k₀ρ)e^{imθ}. Inside the cylinders the user may have to choose the {Jₘ,Yₘ} pair because the Hankel functions are both singular at the origin. This behavior comes from the Yₘ part of the Hankel function, which is given by: Hₘ⁽¹⁾=Jₘ+iYₘ,Hₘ⁽²⁾=jₘ−iYₘ. Thus, only the Jₘ functions can be kept for the interior. In this case the total internal field is Eₜₒₜ^{int}=Σ_{m=-∞}^{∞}aₘJₘ(k₁ρ)e^{imθ}.

After expressing the incident field in polar coordinates, i.e., in a Fourier-Bessel series, the electric and magnetic field continuity conditions can be imposed at the boundaries of each cylinder. The result is a system of equations with the unknowns being the Fourier-Bessel coefficients of the scattered field outside the cylinders, and the total field inside the cylinders. The system may be simplified by using the relationship between the Bessel-Fourier coefficients of a field incident on a cylinder and the coefficients for the scattered and internal fields.

The optimization process will now be described in more detail. In one embodiment, the optimization may be based on minimizing of a functional. The functional may be defined as the residual error between the calculated angular distribution of the normal component of the Poynting vector S and a distribution expressed as a target and the result. In 2D the error may be calculated along an observation line, for example a circle around the group of cylinders. This line may be divided into small portions and the normal component of the S vector may be calculated in the center of each segment.

The target function T(α) may represent the angular distribution of intensity exiting the circular observation region, and Sₙ(α) may represent the normal component of the real part of the Poynting vector, i.e. Sₙ(α)=S(α)·n(α) where n is the normal unit vector. In this space of functions defined on [0°, 360°] and having real values, the user may define a “distance” D between result Sₙ(α) and target T(α) as follows: D=½π∫₀^{2π}|Sₙ(α)−T(α)|^{γ}dα. To properly evaluate the difference between the target and result, the functions T and S may have to be similarly normalized.

In general, the exponent γ may take any value. Choosing γ=1 may assure that each improvement is considered with the same weight. When choosing γ>1, improvements made in regions where the target and the results are very different may influence the integral D more than a few smaller improvements in other regions. This may mean that γ=1 tends to ensure an uniform convergence, while γ>1 favors reduction of major differences between target and result. The greater the numerical value of γ, the more important this effect may become, while for 0<γ<1 the effect may be reversed. A negative exponent γ may tend to push the solution further away from the target, in a manner which may depend on the numerical value of γ.

Different exponents may be used for different stages of the iterative process. For example γ=1 could be used at the beginning of the convergence procedure to avoid local minima. Later, the value of γ may be increased to accelerate convergence towards a minimum. Furthermore, should this minimum not be sufficiently close to the target function, application of a negative exponent may divert the iterations from this local minimum to some intermediate point where γ>1 iterations could be restarted in the search for a better minimum.

The real part of the Poynting vector may be used in calculating Sₙ(α). For most scattering directions, this may be the Poynting vector of the total field, with the exception of the input beam region where the scattered field S vector is used for the top-hat target function, and the difference between the Poynting vector of the input field and total field is used for the cos² target function.

The distances, or errors, D may be computed numerically, by dividing the observation circle into very small and equal portions and the integral replaced by a sum over these portions:

$${D}^{*} = {\sum }_{i = 0}^{Np} {\vert \frac{{S}_{n} ( {α}_{1} )}{{N}_{s}} - \frac{T ( {α}_{1} )}{{N}_{1}} \vert}^{γ}$$

where N_{S} and N₁ are normalization factors. Different normalization methods can be used such as normalization to the maximum value, normalization to the sum of all values, or normalization to the sum of the squares. In the embodiments described in the present disclosure, the normalization may be chosen to be the sum, i.e. the total power, since the functions involve intensity.

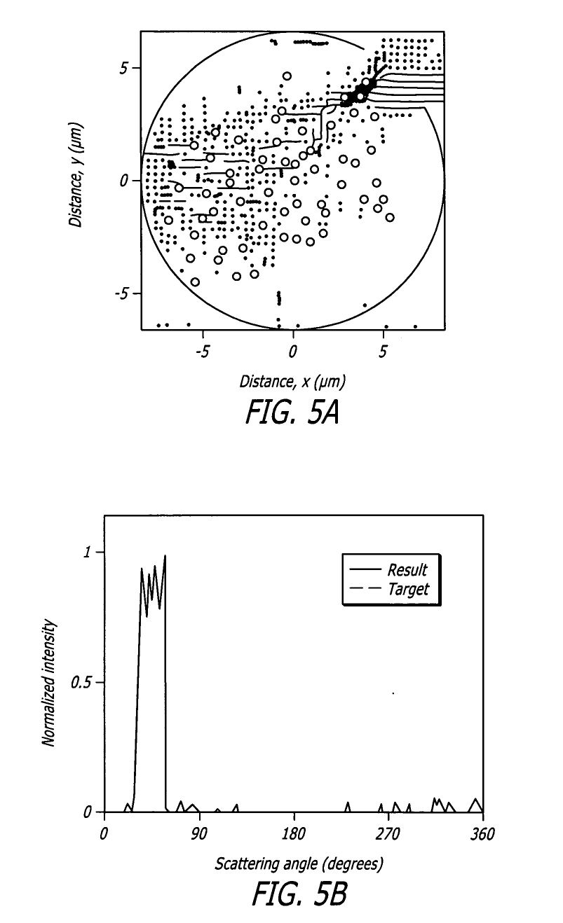

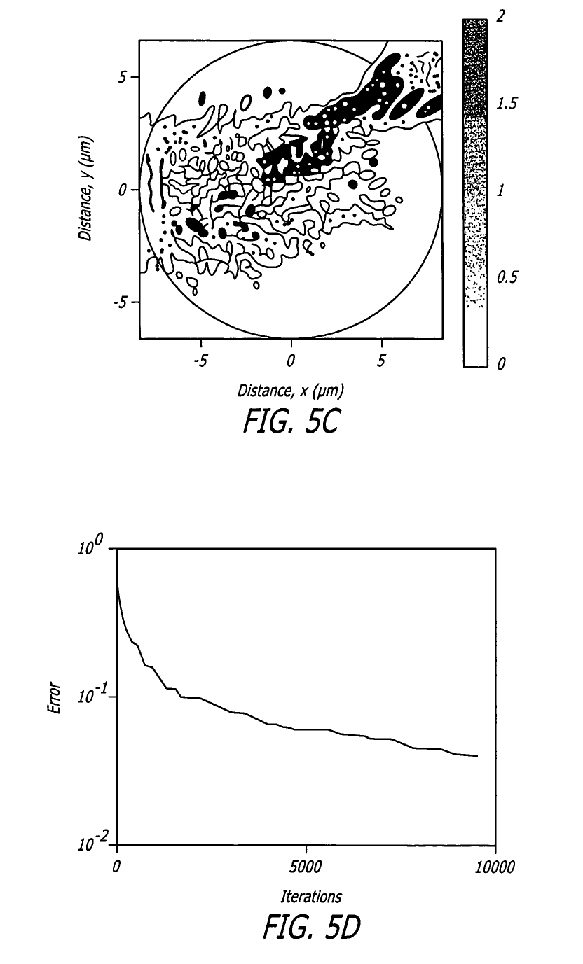

FIGS. 5A, 5B, 5C, and 5D illustrate the numerically optimized spatial configuration of the 56 dielectric cylinders (described above in conjunction with FIGS. 4A and 4B), when the adaptive algorithms described above have been implemented. In particular, FIG. 5A shows the spatial distribution of the N=56 rods with the real part of Poynting vectors, after 9700 iterations of the adaptive search algorithm described above. FIG. 5B shows the corresponding angular distribution of the intensity. In FIG. 5C, the distribution of the electric field (relative magnitude, with one corresponding to the maximum magnitude in the incident Gaussian beam) is shown.

In FIG. 5D, the relative error versus number of iterations are represented. The errors have been normalized with respect to the initial value. FIG. 5D shows that for this system with 2×N positional degrees of freedom, the error is not saturated even after 9700 iterations, and the spatial configuration of cylinders could be further optimized by performing additional iterations. The error curve shown in FIG. 5D is computed using the method described above, with exponent γ=2 on the observation circle of radius 7 μm.

FIGS. 4A-4B, and FIGS. 5A-5D show that for starting configurations in which cylinders are randomly positioned, the convergence rate towards the target is approximately the same. On the other hand, if the iterative procedure starts with a quasioptimal configuration, the number of iterations needed can be small.

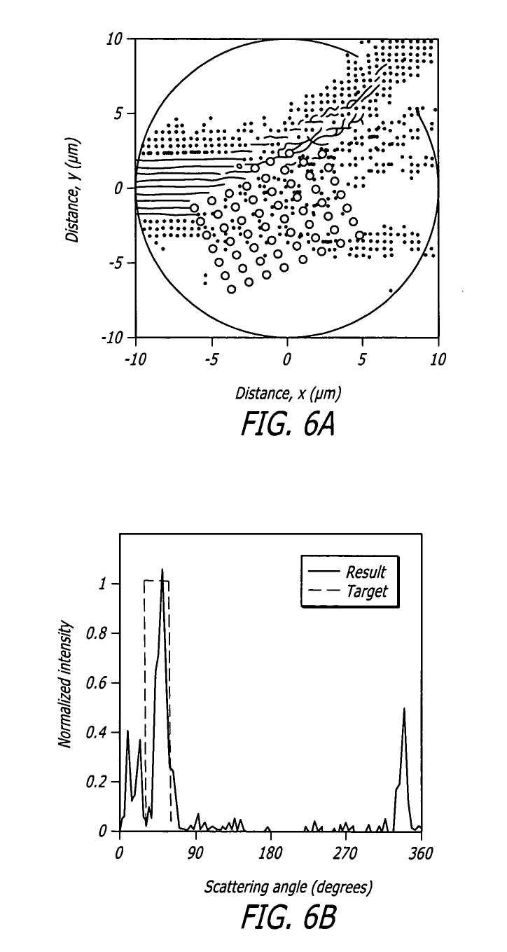

For comparison, in FIGS. 6A and 6B the results of using a periodic crystal that does not have a broken symmetry are shown. The number of dielectric rods is the same, namely N=56. FIGS. 6A and 6B show that with a periodic, spatially symmetric configuration, the number (56) of rods is not sufficient to redirect all the beam in the 45° (±15°) direction, that much of the scattered field falls outside the target area, and that the error with respect to the target function is unacceptably large. The spatial symmetry of periodic photonic crystals may exclude the realization of the functionalities described above for the top hat target function. Only by breaking a spatial symmetry may such target responses be achieved. FIGS. 6A and 6B illustrate that, in general, a broken symmetry enables functionality.

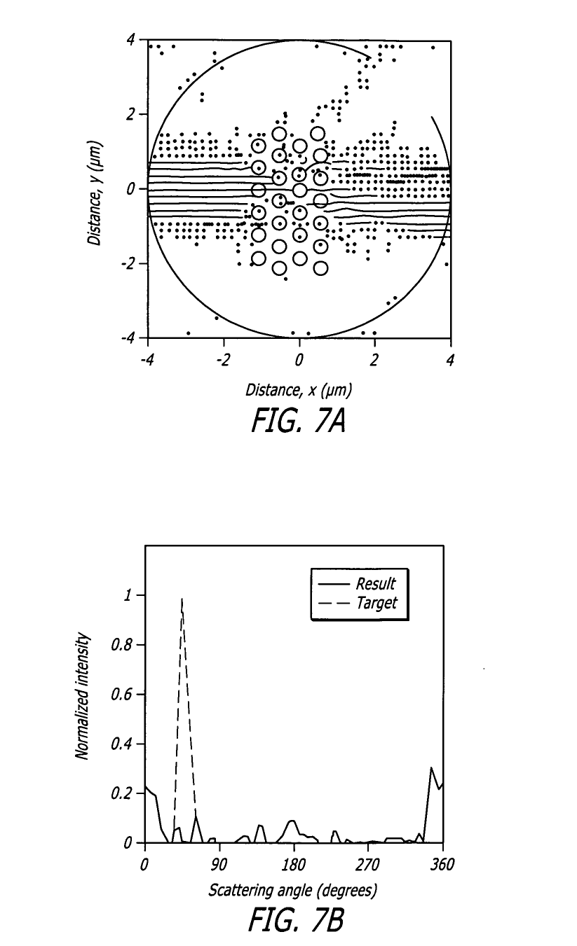

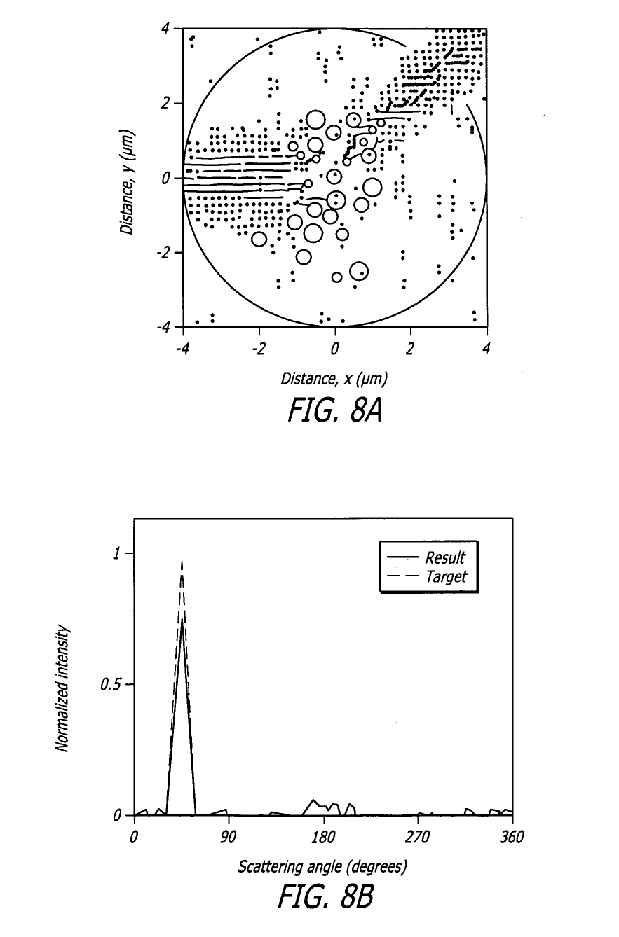

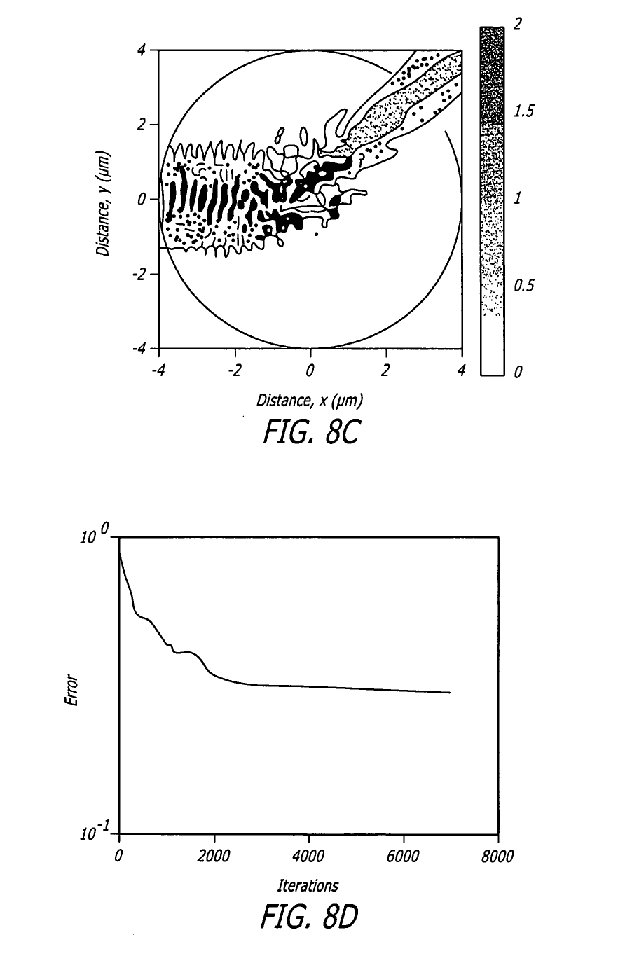

FIGS. 7A-7B, and 8A-8D illustrate an embodiment in which a cosine squared intensity distribution is chosen as the desired target function. A cosine squared intensity distribution target function approximates the transverse spatial mode intensity typically found in a waveguide. Therefore, this type of target intensity distribution may be a first step toward design of a waveguide coupler. In this embodiment, a nanophotonic device is considered that includes N=26 lower index cylinders (SᵢO₂, n=1.45) embedded in a higher index material (Sᵢ, n=3.5). In the illustrated embodiment, the incident wave is a TE polarized (magnetic field along the z direction) Gaussian beam of width 2σ=1.5 μm and wavelength λ=1.5 μm. The initial configuration of the cylinders and the resulting intensity distribution are illustrated in FIGS. 7A and 7B, respectively.

In FIGS. 8A, 8B, 8C, and 8D, the optimized spatial configuration, the Poynting vectors, the relative magnitude of the magnetic field (with one corresponding to the maximum magnitude in the original Gaussian beam), and the relative error versus the number of iterations, respectively. In this embodiment, the position of the N=26 cylinders and their diameters d could be changed, providing a total number of degrees of freedom that is three times the number of cylinders N. The values of the diameters were constrained to the range 02≦d≦0.5 μm. The error was computed using the metric described above, with exponent γ=1 on a 6 μm radius circle. Due to the small number of cylinders, the actual number of degrees of freedom is smaller (78) relative to the previous calculations with a top-hat target function (112), and the optimization saturates after a comparatively small number of iterations N.

Optimization algorithms using 2D electromagnetic solvers may be more computationally intensive than those for ID structures. The compute time for the forward problem solver may be dominated by the solution of a linear system with a full matrix of complex numbers and thus is strongly dependent on the number of cylinders N considered in the problem and the number of Bessel functions Nb used. The size of the system is Nₘ=N(2N_{b}+1) and the solver routine time may be proportional to the cube of the matrix size O(Nₘ³). When using an incident plane wave or a cylindrical wave, the number of Bessel functions needed is very small. An appropriately accurate approximation of the Gaussian beam shape requires, however, a large number of Bessel functions and a corresponding increase in compute time.

In sum, in section II of this disclosure the adaptive design of aperiodic nanophotonic dielectric structures has been described. Adaptive algorithms have been described that can be tailored to closely match desired electromagnetic transmission and scattering properties. The broken symmetry of the resulting configuration allows more degrees of freedom, and allows for the possibility of better optimization, compared to spatially symmetric photonic crystal structures.

While certain embodiments have been described of systems and methods for adaptive design of photonic and electronic semiconductor devices, it is to be understood that the concepts implicit in these embodiments may be used in other embodiments as well. The protection of this application is limited solely to the claims that now follow.

In these claims, reference to an element in the singular is not intended to mean “one and only one” unless specifically so stated, but rather “one or more.” All structural and functional equivalents to the elements of the various embodiments described throughout this disclosure that are known or later come to be known to those of ordinary skill in the art are expressly incorporated herein by reference, and are intended to be encompassed by the claims. Moreover, nothing disclosed herein is intended to be dedicated to the public, regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A QCSE (quantum confined Stark effect) device comprising:
a semiconductor quantum well structure having an energy band profile defined by a broken-symmetry quantum well potential; and
a processing system configured to adaptively search for and numerically optimize the broken-symmetry quantum well potential, in order to most closely match a desired target response of the QCSE device to incident optical radiation.

2. The QCSE device of claim 1,
wherein the quantum well structure is configured to cause excitons to be created when photons of the incident optical radiation are absorbed by the quantum well structure;
wherein an optical absorption of the quantum well structure varies as a function of an electric field applied substantially perpendicular to a plane of the quantum well potential V(x); and
wherein the desired target response of the quantum well structure comprises a desired variation of an absorption spectrum of the excitons, as a function of the applied electric field.

3. The QCSE device of claim 1, wherein the QCSE device is one of an optical modulator and an optical detector.

4. The QCSE device of claim 1, wherein the processing system is further configured to adaptively search for the quantum well potential by performing an unbiased stochastic search of a configuration space for the quantum well structure.

5. The QCSE device of claim 1, wherein the processing system is further configured to:
determine an exciton wave function that depends upon a variational parameter λ;
vary the parameter λ to minimize a binding energy of the exciton and to optimize the exciton wave function, and to compute a contribution of the excitons to an absorption spectrum of the photons so as to generate the exciton absorption spectrum.

6. The QCSE device of claim 5,
wherein the exciton comprises an electron and a hole;
wherein the exciton wave function comprises a many-body wave function Ψₑₓ; and
wherein the processing system is further configured to determine the exciton many-body wave function by finding single-particle eigenfunctions of the electron and the hole along a direction of the applied electric field; and
wherein the many-body exciton wave function Ψₑₓ is given by:
Ψₑₓ(xₑ,xₕ,ρ)=\sqrt{2/π}Ψₑ(xₑ)Ψₕ(xₕ)exp(−ρ/λ)/λ
wherein Ψₑ(xₑ) represents a single-particle eigenfunction of the electron;
wherein Ψₕ(xₕ) represents a single-particle eigenfunction of the hole;
wherein xₑ and xₕ represent coordinates of the electron and the hole, respectively;
wherein ρ represents a separation between the electron and the hole in the plane of the quantum well, and perpendicular to the applied electric field; and
wherein λ represents the variational parameter for the many-body exciton wave function Ψₑₓ.

7. The QCSE device of claim 5, wherein the processing system is further configured to use a nearest-neighbor tight-binding Hamiltonian H_{unc} for an uncorrelated electron and hole pair to find the single-particle eigenfunctions Ψₑ(xₑ) and Ψₕ(xₕ) of the electron and the hole, and wherein the Hamiltonian H_{unc} for the uncorrelated electron and hole pair is given by a sum of a Hamiltonian Hₑ of the uncorrelated electron and a Hamiltonian Hₕ of the uncorrelated hole, and wherein H_{unc}, Hₑ, and Hₕ are given as follows:
$$\begin{matrix}{H}_{unc} = {H}_{e} + {H}_{h} \\ = - {t}_{e} {\sum }_{< i , j >} ( {c}_{ei}^{+} {c}_{ej} + {c}_{ej}^{+} {c}_{ei} ) + {\sum }_{i} {ɛ}_{ei} + {t}_{h} {\sum }_{< i , j >} ( {c}_{hi}^{+} {c}_{hj} + {c}_{hj}^{+} {c}_{hi} ) + \\ {\sum }_{i} {ɛ}_{hi} ,\end{matrix}$$
wherein tₑ denotes an electron hopping energy;
tₕ represents a hole hopping energy;
εₑ denotes an onsite electron energy;
εₕ denotes an onsite hole energy;
cₑ⁺ and cₑ denote an electron creation and an electron annihilation operator, respectively;
cₕ⁺ and cₕ denote a hole creation and a hole annihilation operator, respectively; and
<i, j> indicates a sum over nearest neighbors only.

8. The QCSE device of claim 5, wherein the processing system is further configured to find the exciton many body wave function Ψₑₓ by varying the parameter λ to minimize the exciton binding energy using an exciton Hamiltonian Hex, and wherein the exciton Hamiltonian Hₑₓ is given by:
$${H}_{ex} = {H}_{e} + {H}_{h} - \frac{{h}^{2} {∇}_{ρ}^{2}}{2 μ} - \frac{{ⅇ}^{2}}{4 {πɛ}_{0} {ɛ}_{r}} \frac{1}{\sqrt{{ρ}^{2} + {( {z}_{e} - {z}_{h} )}^{2}}} ,$$
wherein
$$\frac{{h}^{2} {∇}_{ρ}^{2}}{2 μ}$$
represents an in-plane kinetic energy of the electron and the hole about their center-of-mass,
$$\frac{{ⅇ}^{2}}{4 {πɛ}_{0} {ɛ}_{r}} \frac{1}{\sqrt{{ρ}^{2} + {( {z}_{e} - {z}_{h} )}^{2}}}$$
represents a Coulomb potential energy between the electron and the hole,
μ represents a reduced mass;
eᵣ represents a relative dielectric permittivity;
zₑ represents a coordinate of a center of mass of the electron; and
zₕ represents a coordinate of a center of mass of the hole.

9. The QCSE device of claim 5, wherein the processing system is further configured to compute a contribution from a particle-hole continuum, to generate the exciton absorption spectrum.

10. The QCSE device of claim 1, wherein the processing system is configured to perform the numerical optimization by:
developing a fitness function; and
optimizing the fitness function using a genetic algorithm.

11. The QCSE device of claim 10, wherein the fitness function is adapted to simultaneously optimize, at selected values of the applied electric field, a strength of an exciton absorption peak, and a separation of the exciton absorption peak.

12. The QCSE device of claim 1, further comprising:
an optical source configured to generate optical radiation directed to the quantum well structure; and
an optical detector configured to detect and measure an optical response of the quantum well structure to the optical radiation from the optical source.

13. A nanophotonic device, comprising:
a plurality of dielectric elements arranged within a substantially uniform medium in an aperiodic spatial configuration, each of the dielectric elements configured to scatter incoming optical radiation; and
a processing system adapted to compute and optimize the spatial configuration of the dielectric elements within the medium in order to most closely generate a desired target function response from the nanophotonic device in response to the incoming optical radiation.

14. The nanophotonic device of claim 13, wherein the processing system is further configured to optimize the spatial configuration by minimizing a residual error between an angular distribution of a normal component of a Poynting vector S of the scattered field of optical radiation, as computed by the processing system, and the desired target function response.

15. The nanophotonic device of claim 13, wherein the processing system is further configured to:
a) initially choose a trial spatial configuration of the dielectric elements;
b) analytically solve Helmholtz equations to compute initial scattered fields that would result from scattering of the incident optical radiation from the dielectric elements if the dielectrics elements were arranged in accordance with the trial configuration;
c) modify the spatial configuration of the dielectric elements by randomly changing position of one or more of the dielectric elements, by a small amount;
d) calculating modified scattered fields in the modified spatial configuration of the dielectric elements;
e) computing an error function that compares a first value and a second value, the first value representing a difference between the modified scattered fields and the desired target function response, the second value representing a difference between the initial scattered fields and the desired target function response;
wherein the modified spatial configuration is accepted if the first value is smaller than the second value, otherwise is rejected; and
f) iterating steps c), d), and e), until the modified spatial configuration of the dielectric elements is accepted.

16. The nanophotonic device of claim 13, wherein the desired target function response comprises at least one of:
a desired intensity distribution of optical radiation scattered from the plurality of dielectric elements;
a redirecting and a reshaping of an incoming beam of optical radiation;
a desired reflectivity R(E) of incident optical radiation, as a function of energy E; and
a desired transmissivity T(E) of incident optical radiation, as a function of energy E.

17. The nanophotonic device of claim 16, wherein the desired intensity distribution of the scattered optical radiation comprises a top-hat intensity distribution, and wherein the nanophotonic device is configured to provide a substantially uniform near field illumination.

18. The nanophotonic device of claim 16, wherein the desired intensity distribution of the scattered optical radiation comprises a cosine squared intensity distribution, and wherein the nanophotonic device is configured to provide coupling to a waveguide.

19. The nanophotonic device of claim 13, wherein each one of the dielectric elements have a substantially cylindrical configuration.

20. The nanophotonic device of claim 13, wherein each one of the dielectric elements have substantially identical sizes and shapes.

21. The nanophotonic device of claim 13, wherein the device is at least one of:
an optical scatterer;
an optical reflector;
an optical transmitter;
an optical waveguide;
an optical wavelength filter;
an optical beam redirector; and
an optical modulator.

22. The nanophotonic device of claim 13, further comprising:
an optical source configured to generate optical radiation directed to the plurality of dielectric elements; and
an optical detector configured to detect and measure an optical response of the nanophotonic device to the optical radiation from the optical source.

23. A nanophotonic device, comprising:
a plurality of dielectric elements distributed in an aperiodic, broken-symmetry spatial configuration within a substantially uniform medium, each dielectric element configured to scatter incoming optical radiation;
wherein the spatial configuration of the dielectric elements is numerically computed and optimized so as to most closely generate a desired target function response from the nanophotonic device in response to incoming optical radiation.

24. A QCSE (quantum confined Stark effect) device comprising:
a semiconductor quantum well structure having an energy band profile defined by a broken-symmetry quantum well potential V(x), the quantum well structure including a plurality of semiconductor layers having different band gap energies;
wherein the broken-symmetry quantum well potential V(x) is numerically computed and optimized so as to most closely match a desired target response of the QCSE device to incident optical radiation.
